(19) United States
(12) Patent Application Publication
(10) Pub. No.: US 2012/0049250 A1
(43) Pub. Date: Mar. 1, 2012

(54) Semiconductor Integrated Circuit Device Including an Epitaxial Layer

(76) Inventors: Sang-Jine Park, Yongin-si (KR); Bo-Un Yoon, Seoul (KR); Jeong-Nam Han, Seoul (KR); Jae-Jik Baek, Seongnam-si (KR); Byung-Kwon Cho, Suwon-si (KR)

(21) Appl. No.: 13/191,055

(22) Filed: Jul. 26, 2011

(30) Foreign Application Priority Data
Aug. 25, 2010 (KR) 10-2010-0082485

(51) Int. Cl. H01L 29/78

(52) U.S. Cl. 257/288; 257/E29.255

(57) ABSTRACT

A semiconductor integrated circuit device includes a substrate. A gate structure is formed on the substrate and includes a gate insulating film and a gate electrode. A first sidewall spacer is formed on two sidewalls of the gate structure. A second sidewall spacer is formed on the first sidewall spacer. A recess compensation film is interposed between the second sidewall spacer and the substrate. An epitaxial layer is in contact with the recess compensation film.

### CROSS-REFERENCE TO RELATED APPLICATIONS

This application claims priority from Korean Patent Application No. 10-2010-0082485 filed on Aug. 25, 2010 in the Korean Intellectual Property Office, the disclosure of which is incorporated herein by reference in its entirety.

### BACKGROUND

1. Technical Field

The present invention relates to a semiconductor integrated circuit device, and more particularly, to a semiconductor integrated circuit device including an epitaxial layer.

2. Discussion of the Related Art

Metal oxide semiconductors are field-effect transistors having a metal gate electrode placed on top of an oxide insulator which is on top of a semiconductor material. The conductive channel of the metal oxide semiconductor may either be n-type, in which case electrons are conducted therethrough or p-type, in which case holes are conducted therethrough. It has been demonstrated that by applying mechanical stress in the channel region, operating current of semiconductor integrated circuit devices based on the metal oxide semiconductors can be increased. Accordingly, stress formed in a channel region, for example, by the application of mechanical stress, affects the mobility of the carriers.

Compressive stress formed in a channel region of a p-channel metal oxide semiconductor (PMOS) transistor increases the mobility of hole carriers. The compressive stress can be applied to the channel region of the PMOS transistor, for example, by forming a trench in a source/drain region of the PMOS transistor and forming a SiGe layer in the trench.

### SUMMARY

Exemplary aspects of the present invention provide a semiconductor integrated circuit device in which transistors have stable driving capabilities.

According to an exemplary aspect of the present invention, there is provided a semiconductor integrated circuit device including a substrate. A gate structure is formed on the substrate and includes a gate insulating film and a gate electrode. A first sidewall spacer is formed on both sidewalls of the gate structure. A second sidewall spacer is formed on the first sidewall spacer. A recess compensation film is interposed between the second sidewall spacer and the substrate. An epitaxial layer is in contact with the recess compensation film.

According to an exemplary aspect of the present invention, there is provided a semiconductor integrated circuit device including a substrate. A gate structure is formed on the substrate and includes a gate insulating film and a gate electrode. A sidewall spacer is formed on both sidewalls of the gate structure. A recess compensation film is interposed between the sidewall spacer and the substrate. An epitaxial layer is in contact with the recess compensation film.

According to an exemplary aspect of the present invention, there is provided a semiconductor integrated circuit device including a substrate which includes a first region and a second region. A gate structure is formed on the substrate and includes a gate insulating film and a gate electrode. A first sidewall spacer is formed on both sidewalls of the gate structure. A second sidewall spacer is formed on the first sidewall spacer. A recess compensation film is interposed between the second sidewall spacer and the substrate. An epitaxial layer is in contact with the recess compensation film. The recess compensation film of the first region is aligned with the second sidewall spacer and the recess compensation film of the second region protrudes further than the second sidewall spacer and extends on an upper surface of the substrate.

### BRIEF DESCRIPTION OF THE DRAWINGS

The above and other aspects and features of the present invention will become more apparent by describing in detail exemplary embodiments thereof with reference to the attached drawings, in which:

FIG. 1 is a cross-sectional view of a semiconductor integrated circuit device according to an exemplary embodiment of the present invention;

FIG. 2 is an enlarged view of a portion ‘A’ of FIG. 1;

FIGS. 3 through 6 are cross-sectional views illustrating a method of fabricating a semiconductor integrated circuit device according to an exemplary embodiment of the present invention;

FIG. 7 is a cross-sectional view of a semiconductor integrated circuit device according to an exemplary embodiment of the present invention; and

FIG. 8 is a cross-sectional view of a semiconductor integrated circuit device according to an exemplary embodiment of the present invention.

### DETAILED DESCRIPTION

Aspects and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Like reference numerals may refer to like elements throughout the specification.

It will be understood that when an element is referred to as being “connected to” or “coupled to” another element, it can be directly connected or coupled to the other element or intervening elements may be present.

It will be understood that, although the terms first, second, third, etc., may be used herein to describe various elements, components and/or sections, these elements, components and/or sections should not be limited by these terms.

In the process of fabricating PMOS and NMOS transistors, an impurity ion-implantation process and a photolithography process may be performed on each of the PMOS and NMOS transistors. As these processes are performed, part of a surface of a substrate may be lost. Accordingly, if a trench is formed in the substantially recessed surface of the substrate to provide compressive stress to the channel region and if an epitaxial layer is formed in the trench by filling the trench, the performance of the semiconductor elements may deteriorate. Exemplary embodiments of the present invention may provide for a semiconductor integrated circuit device including an epitaxial layer where deterioration of the performance of the semiconductor elements is reduced or prevented.

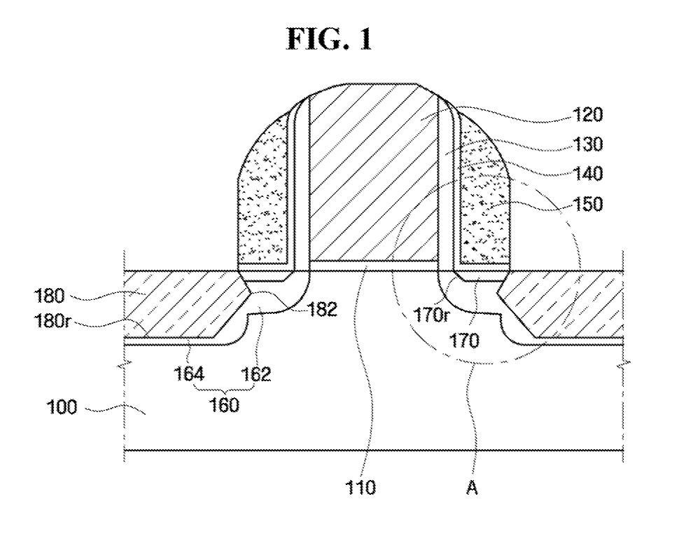

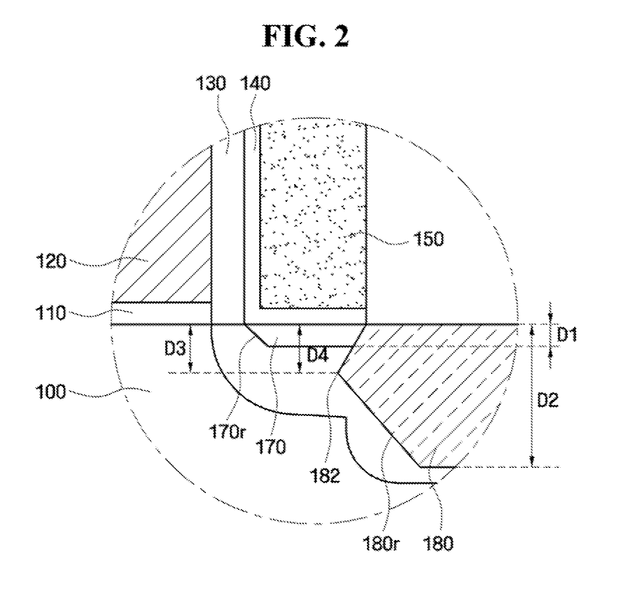

Hereinafter, a semiconductor integrated circuit device according to an exemplary embodiment of the present invention will be described with reference to FIGS. 1 and 2. FIGS. 1 and 2 are cross-sectional views of a semiconductor integrated circuit device according to an exemplary embodiment of the present invention.

Referring to FIG. 1, the semiconductor integrated circuit device according to an exemplary embodiment includes a substrate 100, a gate structure (110 and 120), a first sidewall spacer 130, a second sidewall spacer (140 and 150), a recess compensation film 170, and an epitaxial layer 180.

The substrate 100 may be a silicon substrate, a silicon-on-insulator (SOI) substrate, a silicon germanium substrate, or a substrate of another suitable material.

Although not shown in the drawing, the substrate 100 may include an element isolation region (not shown) which defines an active region. Here, the element isolation region may be a shallow trench isolation (STI) region or a field oxide (FOX) region.

The substrate 100 may include a first impurity region 162 and a second impurity region 164. The first and second impurity regions 162 and 164 may form a source and drain region 160 having a lightly diffused drain (LDD) structure. Although not shown in the drawing, the source and drain region 160 may have various structures. For example, the source and drain region 160 may have a double diffused drain (DDD) structure, a mask islanded double diffused drain (MIDDD) structure, a mask LDD (MLDD) structure, a lateral double-diffused metal oxide semiconductor (LDMOS) structure, or another source and drain structure.

For example, the first impurity region 162 may be aligned with the first sidewall spacer 130. For example, impurities may be implanted into the substrate 100 using the first sidewall spacer 130 as an ion implantation mask. In the case of a p-channel metal oxide semiconductor (PMOS), P-type impurities may be implanted into the substrate 100. The second impurity region 164 may be aligned with the second sidewall spacer (140 and 150). For example, impurities may be implanted into the substrate 100 using the second sidewall spacer (140 and 150) as an ion implantation mask. As shown in the drawing, the second impurity region 164 may have a higher doping concentration than the first impurity region 162 and the second impurity region 164 may be formed deeper than the first impurity region 162.

Here, aligning the first and second impurity regions 162 and 164 with the first sidewall spacer 130 and the second sidewall spacer (140 and 150), respectively, may denote aligning the first and second impurity regions 162 and 164 with an outer sidewall of the first sidewall spacer 130 and an outer sidewall of the second sidewall spacer (140 and 150), respectively. However, the first and second impurity regions 162 and 164 are not necessarily fully aligned with the first sidewall spacer 130 and the second sidewall spacer (140 and 150), respectively. The alignment of the first impurity region 162 and the second impurity region 164 respectively with the first sidewall spacer 130 and the second sidewall spacer (140 and 150) may depend on the scope of diffusion of impurities by various thermal processes performed in the process of fabricating the semiconductor integrated circuit device.

The gate structure (110 and 120) may be formed on the substrate 100 and include a gate insulating film 110 and a gate electrode 120. The gate insulating film 110 may be made of SiO2, SiON, Si3N4, GexOyNz, GexSiyOz, a high-k material, or a stack of these materials. Here, the high-k material may contain at least one of HfO2, ZrO2, Al2O3, Ta2O5, hafnium silicate, and zirconium silicate. The gate electrode 120 may be made of polysilicon or polysilicon ion-implanted with impurities.

The first sidewall spacer 130 is formed on both sidewalls of the gate structure (110 and 120). The first sidewall spacer 130 may be made of an insulating material such as silicon oxide, silicon nitride, or silicon oxynitride. The thickness of the first sidewall spacer 130 may vary according to properties of the semiconductor integrated circuit device.

The second sidewall spacer (140 and 150) is formed on the first sidewall spacers 130. As shown in the drawing, the second sidewall spacer (140 and 150) may be formed on both sidewalls of the gate structure (110 and 120). Further, the second sidewall spacer (140 and 150) may include a first sub-spacer 140 and a second sub-spacer 150. The first sub-spacer 140 may be L-shaped. The structure of the second sidewall spacer (140 and 150) is not limited to the one shown in the drawing. For example, the second sidewall spacer (140 and 150) can also be formed as a single spacer.

The recess compensation film 170 is interposed between the second sidewall spacer (140 and 150) and the substrate 100. As shown in the drawing, the recess compensation film 170 may be aligned with the outer sidewall of the second sidewall spacer (140 and 150). For example, the recess compensation film 170 may be formed under the second sidewall spacer (140 and 150) and might not protrude further than the outer sidewall of the second sidewall spacer (140 and 150). Alternatively, the recess compensation film 170 may be formed under the second sidewall spacer (140 and 150) and may be in contact with the epitaxial layer 180.

The epitaxial layer 180 is in contact with the recess compensation film 170. The epitaxial layer 180 may contain, e.g., SiGe. When the epitaxial layer 180 is made of SiGe, stress may be applied to a channel region of the substrate 100 due to the difference in lattice length between Si and Ge. The stress applied to the channel region may increase the performance of the semiconductor integrated circuit device. Here, the epitaxial layer 180 may be formed by epitaxial growth. In addition, although not shown in the drawing, the epitaxial layer 180 may protrude further than an upper surface of the substrate 100.

The structure of the semiconductor integrated circuit device including the recess compensation film 170 will be described in greater detail with reference to FIG. 2.

Referring to FIG. 2, an upper surface of the recess compensation film 170 may be located in substantially the same plane as the upper surface of the substrate 100 on which the gate structure (110 and 120) is disposed. For example, the upper surface of the substrate 100 may have a profile that extends along the gate structure (110 and 120). For example, the upper surface of the substrate 100 may have a profile that extends along a lower surface of the gate insulating film 110, a lower surface of the first sidewall spacer 130, and a lower surface of the recess compensation film 170. Here, the upper surface of a region of the substrate 100 which contacts the gate structure (110 and 120), the upper surface of a region of the substrate 100 which contacts the first sidewall spacer 130, and the upper surface of the recess compensation film 170 which contacts the second sidewall spacer (140 and 150) may all be disposed in substantially the same plane. Accordingly, a lower surface of the gate structure (110 and 120), the lower surface of the first sidewall spacer 130, and the lower surface of the second sidewall spacer (140 and 150) may all be disposed in substantially the same plane.

A first recess region 170r having a first depth D1 may be formed under the second sidewall spacer (140 and 150). After the gate structure (110 and 120) and the first sidewall spacer 130 are formed on the substrate 100, mask formation, ion implantation, mask elimination processes included in the process of fabricating the semiconductor integrated circuit device may be performed to implant impurities into the substrate 100. Part of the substrate 100 may be lost as a result of these processing steps. The first recess region 170r may be filled with the recess compensation film 170, and the recess compensation film 170 may be made of a material containing at least one of Si and Ge.

A second recess region 180r may be adjacent to the first recess region 170r, may be separated further than the first recess region 170r from the gate structure (110 and 120), and/or may have a second depth D2. The second depth D2 may be greater than the first depth D1. The second recess region 180r may be filled with the epitaxial layer 180. The epitaxial layer 180 may contain, e.g., SiGe.

As shown in FIG. 2, the epitaxial layer 180 may include a tip region 182 which protrudes in the direction of the gate structure (110 and 120). The tip region 182 may be located at a third depth D3 from the upper surface of the substrate 100 on which the gate structure (110 and 120) is disposed and may be located at a fourth depth D4 from the upper surface of the recess compensation film 170. Here, the third and fourth depths D3 and D4 may be equal.

As described above, the first recess region 170r may be filled with the recess compensation film 170. Accordingly, the tip region 182 of the epitaxial layer 180 may be disposed substantially adjacent to the channel region. For example, the upper surface of a region of the substrate 100 on which the second sidewall spacer (140 and 150) is disposed is recessed to the first depth D1. However, since the first recess region 170r is filled with the recess compensation film 170, the upper surface of the substrate 100 may remain unrecessed.

The presence of the recess compensation film 170 may cause the tip region 182 of the epitaxial layer 180 to be formed at a relatively higher position than it would otherwise be formed at in the absence of the recess compensation film 170. For example, when the recess compensation film 170 is formed, an upper surface of the epitaxial layer 180 of a predetermined depth may be raised by the thickness of the recess compensation film 170. Accordingly, the tip region 182 of the epitaxial layer 180 may also be raised. The distance between the tip region 182 and the channel region, which may affect the driving capability of the semiconductor integrated circuit device, may be reduced, and the performance of the semiconductor integrated circuit device may be increased.

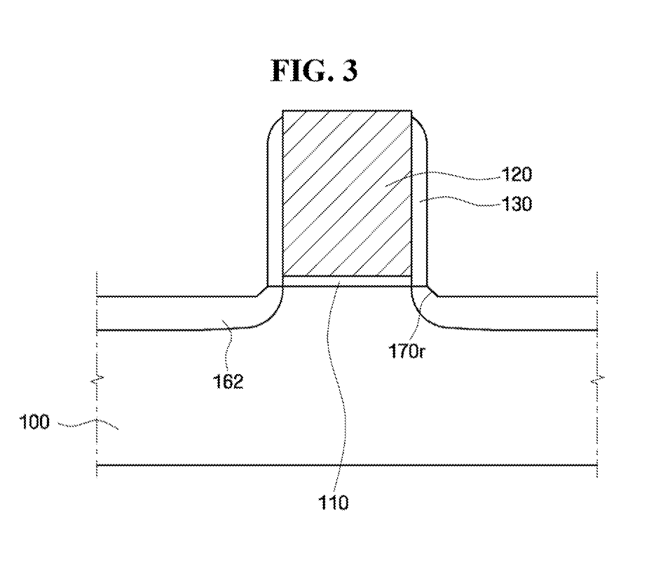

Hereinafter a method of fabricating a semiconductor integrated circuit device according to an exemplary embodiment of the present invention will be described with reference to FIGS. 3 through 6. FIGS. 3 through 6 are cross-sectional views illustrating a method of fabricating a semiconductor integrated circuit device according to an exemplary embodiment of the present invention. Elements substantially identical to the above-described elements may be understood to have the same characteristics described above.

Referring to FIG. 3, a substrate 100 may be provided, and a gate structure (110 and 120) may be formed on the substrate 100. Then, a first sidewall spacer 130 may be formed on both sidewalls of the gate structure (110 and 120), and a lightly doped source/drain region may be formed under the first sidewall spacer 130.

For example, an insulating film forming a gate insulating film and a conductive film forming a gate electrode may be sequentially deposited on the substrate 100 and then patterned to form a gate insulating film 110 and a gate electrode 120. The gate insulating film 110 may be deposited by chemical vapor deposition (CVD), thermal oxidation, sputtering, or by another method. The gate electrode 120 may be a conductor and may be formed by stacking one or more of a polysilicon film doped with n- or p-type impurities, a metal film, a metal silicide layer, and a metal nitride film. Here, metal contained in the gate electrode 120 may be tungsten (W), cobalt (Co), nickel (Ni), titanium (Ti), and/or tantalum (Ta).

The first sidewall spacer 130 may be formed by forming a spacer layer (not shown) forming a sidewall spacer on the substrate 100, on which the gate structure (110 and 120) is formed, and anisotropically etching the spacer layer. The first sidewall spacer 130 may be made of a nitride or an oxide.

A first impurity region 162 may be formed by performing an ion implantation process using the first sidewall spacer 130 as a mask. As shown in the drawing, the first impurity region 162 may be diffused toward the inside of the first sidewall spacer 130, for example, toward the gate structure (110 and 120) by a subsequent process, e.g., a heat-treatment process.

Although not shown in the drawing, a mask pattern, e.g., a photoresist pattern may be formed on the substrate 100 and desired impurities may be selectively implanted into an particular region. For example, as the substrate 100 goes through a photolithography process, which includes photoresist coating, patterning and ashing processes, and the ion implantation process, part of the upper surface of the substrate 100 may be lost. Thus, as shown in FIG. 3, a first recess region 170r may be formed on the upper surface of the substrate 100.

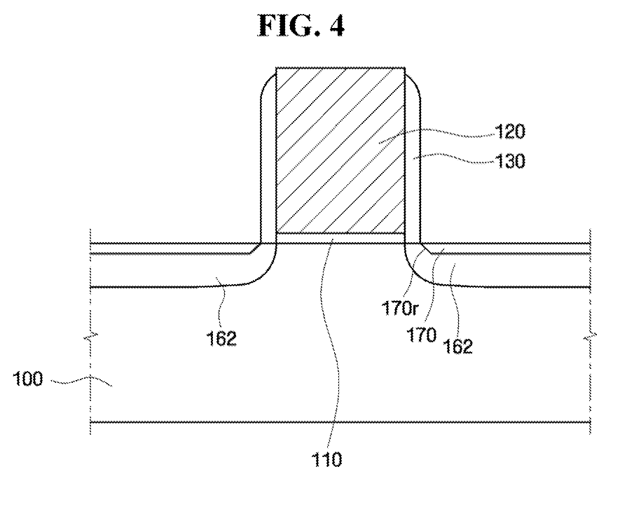

Referring to FIG. 4, the first recess region 170r is filled with a recess compensation film 170.

For example, the first recess region 170r may be filled with a material that contains at least one of Si and Ge. As shown in the drawing, an upper surface of the recess compensation film 170 may be disposed in substantially the same plane as the upper surface of a region of the substrate 100 on which the gate structure (110 and 120) is formed. In some exemplary embodiments, the upper surface of the recess compensation film 170 may protrude further than the upper surface of the region of the substrate 100 on which the gate structure (110 and 120) is formed.

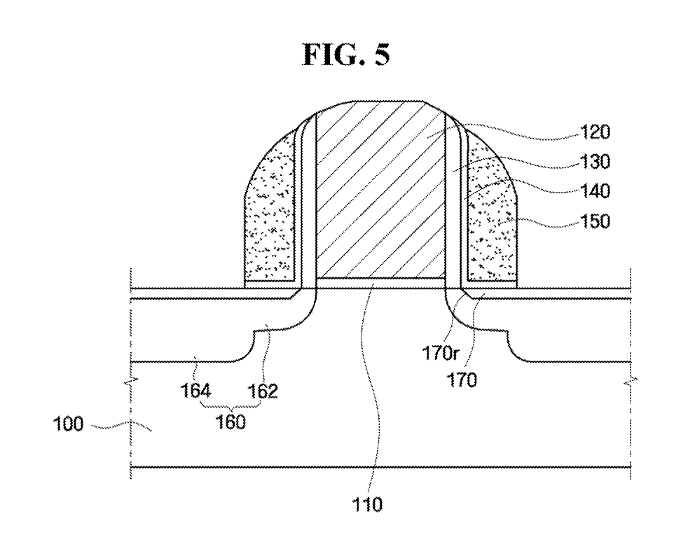

Referring to FIG. 5, a second sidewall spacer (140 and 150) may be formed, and a second impurity region 164 may be formed using the second sidewall spacer (140 and 150) as a mask.

For example, the second sidewall spacer (140 and 150) may be formed on the recess compensation film 170 that fills the first recess region 170r. As described above, the second sidewall spacer (140 and 150) includes a first sub-spacer 140 and a second sub-spacer 150. The first sub-spacer 140 and the second sub-spacer 150 may each be formed in various ways.

The second impurity region 164 may be formed by ion-implanting impurities using the second sidewall spacer (140 and 150) as a mask. As described above, the second impurity region 164 may be formed to a higher doping concentration and to a greater depth than the first impurity region 162.

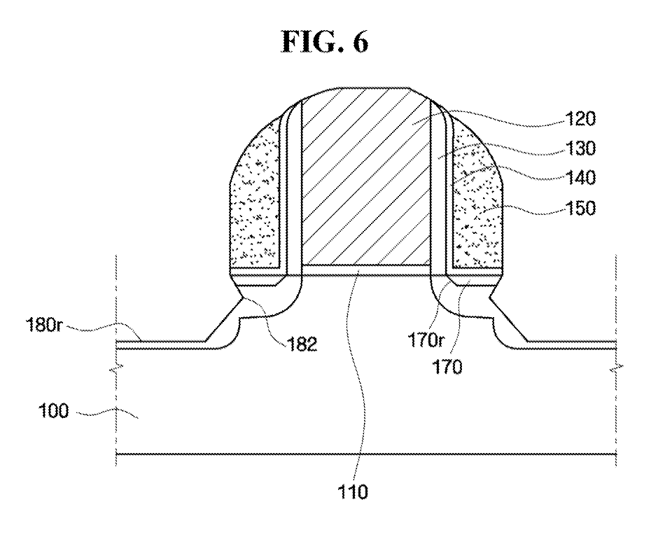

Referring to FIG. 6, a second recess region 180r is formed in contact with the recess compensation film 170.

For example, the recess compensation film 170 and the substrate 100 are etched using the second sidewall spacer (140 and 150) as a mask. The second recess region 180r is formed thereby. At least one etching process may be performed to form the second recess region 180r. For example, a dry-etching process may be performed to form a preliminary recess, and then a wet-etching process may be performed to complete the second recess region 180r. Since an etchant used in the wet-etching process etches the crystal face of the substrate 100, the second recess region 180r may have a hexagonal profile (or a sigma shape) after the wet-etching process. The etchant may be, for example, tetramethylammonium hydroxide (TMAH) or ammonium hydroxide.

Accordingly, referring to FIG. 6, the second recess region 180r may have a profile including a tip region 182 that protrudes in the direction of the gate structure (110 and 120). As described above, an etching process forming the second recess region 180r starts from the upper surface of the recess compensation film 170 formed on the substrate 100. Thus, even when the second recess region 180r is formed to an desired depth, a depth of the tip region 182 may be raised by a thickness of the recess compensation film 170. Here, the depth of the tip region 182 may denote a vertical distance from the upper surface of the substrate 100 on which the gate structure (110 and 120) is formed to the tip region 182.

Referring back to FIG. 1, an epitaxial layer 180 is formed by filling the second recess region 180r.

The epitaxial layer 180 may contain SiGe. For example, the epitaxial layer 180 may be formed using at least one of a Si-containing source gas, a Ge-containing source gas, and a SiGe-containing source gas. Here, the epitaxial layer 180 may be formed by, e.g., selective epitaxial growth. As described above, the distance between a channel region and the tip region 182 of the epitaxial layer 180 affects the performance of the semiconductor integrated circuit device. Thus, by forming the tip region 182 at a relatively raised position, the performance of the semiconductor integrated circuit device can be increased.

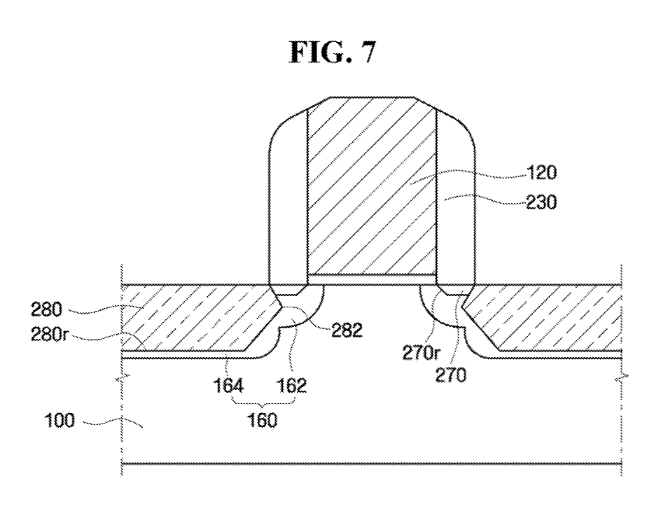

Hereinafter, a semiconductor integrated circuit device according to an exemplary embodiment of the present invention will be described with reference to FIG. 7. FIG. 7 is a cross-sectional view of a semiconductor integrated circuit device according to an exemplary embodiment of the present invention.

The semiconductor integrated circuit device according to an exemplary embodiment may be different from the semiconductor integrated circuit device described above in that the semiconductor integrated circuit device may include one sidewall spacer and a first impurity region may be aligned with a gate structure. Elements may be substantially identical to those of the semiconductor integrated circuit device described above except as noted.

Referring to FIG. 7, the semiconductor integrated circuit device according to an exemplary embodiment includes a substrate 100, a gate structure (110 and 120), a sidewall spacer 230, a recess compensation film 270, and an epitaxial layer 280.

The sidewall spacer 230 is formed on both sidewalls of the gate structure (110 and 120). The sidewall spacer 230 may be, for example, an oxide film or a nitride film. A first impurity region 162 may be aligned with the gate structure (110 and 120), and a second impurity region 164 may be aligned with the sidewall spacer 230. As in the previous embodiments, the first and second impurity regions 162 and 164 may be diffused toward a gate electrode 120 by a subsequent heat-treatment process, as shown in the drawing.

A recess compensation film 270 is interposed between the sidewall spacer 230 and the substrate 100. The recess compensation film 270 may be aligned with an outer sidewall of the sidewall spacer 230. For example, the recess compensation film 270 may be formed under the sidewall spacer 230 and may not protrude further than the outer sidewall of the sidewall spacer 230. Alternatively, the recess compensation film 270 may be formed under the sidewall spacer 230 and may contact an epitaxial layer 280.

As described above, mask formation, ion implantation, and mask elimination processes forming impurity regions may be performed before the sidewall spacer 230 is formed. Part of the substrate 100 may be lost during these processing steps thereby forming a first recess region 270r. For example, the first recess region 270r may be formed under the sidewall spacer 230.

The recess compensation film 270 that fills the first recess region 270r may cause the epitaxial layer 280 to be elevated by a thickness of the recess compensation film 270. An upper surface of the recess compensation film 270 may be located in substantially the same plane as an upper surface of the substrate 100 on which the gate structure (110 and 120) is disposed. The formation of the recess compensation film 270 and the elevation of the epitaxial layer and a tip region 282 by the recess compensation film 270 may be substantially identical to the approach described above.

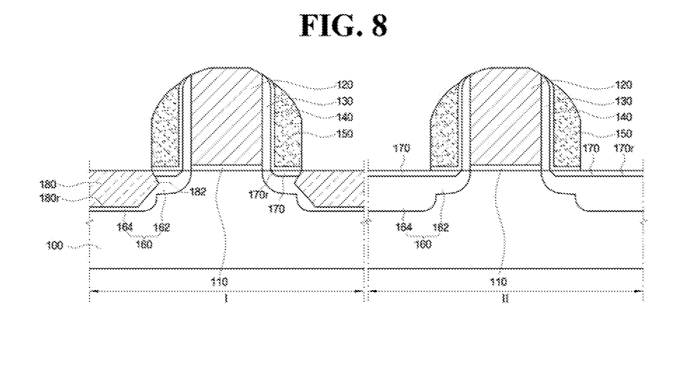

Hereinafter, a semiconductor integrated circuit device according to an exemplary embodiment of the present invention will be described with reference to FIG. 8. FIG. 8 is a cross-sectional view of a semiconductor integrated circuit device according to an exemplary embodiment of the present invention.

The semiconductor integrated circuit device according to an exemplary embodiment may be different from the semiconductor integrated circuit devices described above in that a substrate includes a first region and a second region and that different recess compensation films are formed in the first and second regions. All other features and steps may be substantially identical to those described above.

Referring to FIG. 8, a substrate 100 includes a first region I and a second region II, and a gate structure (110 and 120) is formed in each of the first and second regions I and II.

A p-channel MOS (PMOS) transistor may be formed on the first region I, and an n-channel MOS (NMOS) transistor may be formed on the second region II. Together, the two transistor regions may together form a single Complementary metal oxide semiconductor (CMOS). An epitaxial layer 180 may be formed only in the first region I.

As shown in FIG. 8, a recess compensation film 170 of the first region I may be aligned with a second sidewall spacer (140 and 150), and a recess compensation film 170 of the second region II may protrude further than a second sidewall spacer (140 and 150) and extend on an upper surface of the substrate 100. According to one exemplary configuration, the epitaxial layer 180 may be formed only in the first region I of the substrate 100, for example, in a region where the PMOS transistor is to be formed. In such a case, the performance of the PMOS transistor may be increased.

The epitaxial layer 180 fills a second recess region 180r which is formed using the second sidewall spacer (140 and 150) as a mask. Thus, the recess compensation film 170 of the first region I may be aligned with the second sidewall spacer (140 and 150). Further, the epitaxial layer 180 may contact the recess compensation film 170. When the epitaxial layer 180 is not formed in the second region II, for example, in a region in which an NMOS transistor is to be formed, the recess compensation film 170 that fills the first recess region 170r may extend on the upper surface of the substrate 100. Accordingly, the recess compensation film 170 of the second region II may protrude further than the second sidewall spacer (140 and 150).

As described above, mask formation, ion implantation, and mask elimination processes forming impurity regions may be performed before the second sidewall spacer (140 and 150) is formed. While the substrate 100 goes through these processes, part of the substrate 100 may be lost, thereby forming the first recess region 170r. Accordingly, the first recess region 170r may be formed under the second sidewall spacer (140 and 150).

The recess compensation film 170 that fills the first recess region 170r may cause the epitaxial layer 180 to be elevated by a thickness of the recess compensation film 170. For example, an upper surface of the recess compensation film 170 may be located in substantially the same plane as an upper surface of the substrate 100 on which the gate structure (110 and 120) is disposed. The formation of the recess compensation film 170 and the elevation of the epitaxial layer 180 and a tip region 182 by the recess compensation film 170 may be substantially the same as is described above. While the present invention has been particularly shown and described with reference to exemplary embodiments thereof, it will be understood by those of ordinary skill in the art that various changes in form and detail may be made therein.

1. A semiconductor integrated circuit device comprising:
a substrate;
a gate structure formed on the substrate, the gate structure comprising a gate insulating film and a gate electrode;
a sidewall spacer formed on two sidewalls of the gate structure;
a recess compensation film interposed between the sidewall spacer and the substrate; and
an epitaxial layer in contact with the recess compensation film.

2. The semiconductor integrated circuit device of claim 1, wherein the sidewall spacer comprises a first sidewall spacer part and a second sidewall spacer part and the recess compensation film is interposed between the second sidewall spacer part and the substrate.

3. The semiconductor integrated circuit device of claim 1, wherein an upper surface of the recess compensation film is located in substantially a same plane as an upper surface of a portion of the substrate on which the gate structure is disposed.

4. The semiconductor integrated circuit device of claim 1, wherein the epitaxial layer comprises a tip region which protrudes in a direction of the gate structure, wherein the tip region is located at a first depth measured from an upper surface of a portion of the substrate on which the gate structure is disposed, and the tip region is also located at a second depth measured from the upper surface of the recess compensation film, wherein the first depth and the second depth are substantially equal.

5. The semiconductor integrated circuit device of claim 1, wherein the substrate comprises a first recess region which is formed to a first depth under the sidewall spacer, wherein the first recess region is filled with the recess compensation film.

6. The semiconductor integrated circuit of claim 2, wherein the substrate comprises a first recess region which is formed to a first depth under the second sidewall spacer part, wherein the first recess region is filled with the recess compensation film.

7. The semiconductor integrated circuit device of claim 5, wherein the substrate comprises a second recess region which is adjacent to the first recess region, and the second recess region is separated further than the first recess region from the gate structure and is formed to a second depth that is greater than the first depth, wherein the second recess region is filled with the epitaxial layer.

8. The semiconductor integrated circuit device of claim 1, wherein the recess compensation film contains at least one of Si or Ge.

9. A semiconductor integrated circuit device comprising:
a substrate;
a gate structure formed on the substrate, the gate structure comprising a gate insulating film and a gate electrode;
a sidewall spacer formed on two sidewalls of the gate structure;
a recess compensation film interposed between the sidewall spacer and the substrate; and
an epitaxial layer in contact with the recess compensation film.

10. The circuit device of claim 9, wherein an upper surface of the recess compensation film is located substantially in a same plane as an upper surface of a portion of the substrate on which the gate structure is disposed.

11. The circuit device of claim 9, wherein the epitaxial layer comprises a tip region which protrudes in a direction of the gate structure, wherein the tip region is located at a first depth measured from an upper surface of a portion of the substrate on which the gate structure is disposed, and the tip region is also located at a second depth measured from the upper surface of the recess compensation film, wherein the first depth and the second depth are substantially equal.

12. The circuit device of claim 9, wherein the substrate comprises a first recess region which is formed to a first depth under the sidewall spacer, wherein the first recess region is filled with the recess compensation film.

13. The circuit device of claim 12, wherein the substrate comprises a second recess region which is adjacent to the first recess region, and the second recess region is separated further than the first recess region from the gate structure and is formed to a second depth that is greater than the first depth, wherein the second recess region is filled with the epitaxial layer.

14. The circuit device of claim 9, wherein the recess compensation film contains at least one of Si or Ge.

15. A semiconductor integrated circuit device comprising:
a substrate comprising a first region and a second region;
a gate structure formed on the substrate, and the gate structure comprising a gate insulating film and a gate electrode;
a first sidewall spacer formed on two sidewalls of the gate structure;
a second sidewall spacer formed on the first sidewall spacer;
a recess compensation film interposed between the second sidewall spacer and the substrate; and
an epitaxial layer in contact with the recess compensation film,
wherein a portion of the recess compensation film disposed in the first region is aligned with the second sidewall spacer, and a portion of the recess compensation film disposed in the second region protrudes further than the second sidewall spacer and extends on an upper surface of the substrate.

16. The semiconductor integrated circuit device of claim 15, wherein the epitaxial layer is formed in the first region and is not formed in the second region.

17. The semiconductor integrated circuit device of claim 16, wherein the epitaxial layer comprises a tip region which protrudes in a direction of the gate structure, wherein the tip region is located at a first depth measured from an upper surface of a portion of the substrate on which the gate structure is disposed, and the tip region is also located at a second depth measured from an upper surface of the recess compensation film, wherein the first depth and the second depth are substantially equal.

18. The semiconductor integrated circuit device of claim 15, wherein an upper surface of the recess compensation film is located in substantially a same plane as an upper surface of a portion of the substrate on which the gate structure is disposed.

19. The semiconductor integrated circuit device of claim 15, wherein the recess compensation film contains at least one of Si or Ge.

20-26. (canceled)
